(19) United States
(12) Patent Application Publication
(10) Pub. No.: US 2008/0113517 A1
(43) Pub. Date: May 15, 2008

(54) METHODS OF FABRICATING SEMICONDUCTOR DEVICES INCLUDING SELECTIVELY REACTING REACTANT GASES

(75) Inventors: Ki-Chul Kim, Suwon-si (KR); Jung-Deog Lee, Yongin-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/757,642

(22) Filed: Jun. 4, 2007

(30) Foreign Application Priority Data
Nov. 10, 2006 (KR) 10-2006-0110948

(51) Int. Cl. H01L 21/302

(52) U.S. Cl. 438/725; 257/E21.214

(57) ABSTRACT

A method of fabricating semiconductor devices with improved critical dimension (CD) uniformity is provided. The methods include forming photoresist patterns on an etching target layer, forming polymer layers on photoresist patterns on an etching target layer by selectively reacting a reactant gas with the photoresist patterns to provide different thicknesses of the polymer layers according to the position of the photoresist patterns, and etching the etching target layer using the photoresist patterns and the polymer layers as an etch mask.

### CROSS-REFERENCE TO RELATED PATENT APPLICATION

This application claims priority under 35 U.S.C. §119 to Korean Patent Application No. 10-2006-0110948, filed on Nov. 10, 2006, in the Korean Intellectual Property Office, the disclosure of which is incorporated herein by reference in its entirety.

### FIELD OF THE INVENTION

The present invention relates to methods of fabricating semiconductor devices, and more particularly, to methods of fabricating semiconductor devices that may possess improved critical dimension (CD) uniformity.

### BACKGROUND OF THE INVENTION

When semiconductor devices are fabricated, dry etching equipment may be used in order to form a desired pattern. During this process, critical dimensions (CDs) of semiconductor devices may not be uniform at the center and edges of a semiconductor wafer due, at least in part, to the characteristics of the equipment. In other words, a CD loss occurring in semiconductor devices formed at the edge of the semiconductor wafer is about 7 to 10 nm larger than that occurring in semiconductor devices formed at the center of the semiconductor wafer.

In an attempt to overcome this problem, approaches for improving the CD uniformity of semiconductor devices have been researched and developed. For instance, a mount on which a semiconductor wafer is placed may be subjected to dual temperature control so that the temperature of the edge of the semiconductor wafer may be decreased in order to solve the problem of CD nonuniformity. However, this approach is generally not a fundamental solution.

### SUMMARY OF THE INVENTION

Embodiments of the present invention provide methods of fabricating semiconductor devices with improved critical dimension (CD) uniformity.

According to some embodiments of the present invention, methods of fabricating semiconductor devices include forming photoresist patterns on an etching target layer, forming polymer layers on the photoresist patterns on the etching target layer by selectively reacting a reactant gas with the photoresist patterns to provide different thicknesses of the polymer layers according to the position of the photoresist patterns, and etching an etching target layer using the photoresist patterns and the polymer layers as an etch mask.

According to other embodiments of the present invention, methods of fabricating semiconductor devices include forming polymer layers on a photoresist pattern to provide different thicknesses according to positions of the photoresist pattern by controlling in a chamber in which the process occurs an internal pressure, source power, bias power, and a flow rate of reactant gas, and etching an etching target layer using the photoresist pattern and the polymer layers as an etch mask.

According to some embodiments, the etching target layer may be an interlayer insulating layer. The etching the etching target layer may include etching the interlayer insulating layer to form contact holes or via holes.

According to further embodiments of the present invention, the etching target layer may be a conductive layer. Etching target layer may include etching the conductive layer to form a wiring pattern.

According to still other embodiments, the photoresist pattern is formed on a substrate comprising an etching target layer, and in some embodiments, the photoresist pattern is formed on a semiconductor wafer.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart of a method of fabricating semiconductor devices according to some embodiments of the present invention;

FIGS. 2 through 4 present cross-sectional views of stages in a method of fabricating semiconductor devices according to some embodiments of the present invention;

FIG. 5 presents a flowchart of a method of fabricating semiconductor devices according to other embodiments of the present invention;

FIG. 6 illustrates a dry etching system used in a method of fabricating semiconductor devices according to some embodiments of the present invention;

FIGS. 7 through 10 present cross-sectional views of stages in a method of fabricating semiconductor devices according to other embodiments of the present invention;

FIG. 11 presents a flowchart of a method of fabricating semiconductor devices according to further embodiments of the present invention;

FIGS. 12 and 13 present cross-sectional views of stages in a method of fabricating semiconductor devices according to further embodiments of the present invention;

FIGS. 14 through 16 illustrate graphs showing the results of observations regarding the thickness of a polymer which is formed on a photoresist pattern while changing the pressure within a chamber, the flow rate of reactant gas, and the source power according to some embodiments of the present invention;

FIGS. 17 and 18 illustrate scanning electron microscope (SEM) photographs and graphs, which show the results of observations regarding the thickness of a polymer layer on a photoresist pattern while changing the deposition time of the polymer layer according to some embodiments of the present invention; and

FIGS. 19 and 20 illustrate cross-sectional SEM photographs and plane SEM photographs, which show the results of forming polymer layers having different thicknesses on a photoresist pattern and etching a semiconductor wafer using the polymer layers as etch masks according to some embodiments of the present invention.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The principles and features of this invention may be employed in varied and numerous embodiments without departing from the scope of the present invention. In the drawings, the size and relative sizes of layers and regions may be exaggerated for clarity. The drawings are not necessarily to scale. Like reference numerals designate like elements throughout the drawings.

It will also be understood that when an element or layer is referred to as being “on,” “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, no intervening elements or layers are present. As used herein, the term “and/or” may include any and all combinations of one or more of the associated listed items and may be abbreviated as “/”.

It will also be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a,” “an” and “the” are intended to include the plural forms as well, unless the context clearly indicates otherwise. For example, “a” polymer layer can mean more than one polymer layer unless a single layer is specifically noted.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein. Further, all publications, patent applications, patents, and other references mentioned herein are incorporated by reference in their entirety.

Embodiments of the present invention are described with reference to plan views and cross-sectional illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated as a rectangle will, typically, have rounded or curved features. Thus, the regions illustrated in the figures are schematic in nature of a device and are not intended to limit the scope of the present invention.

The present invention relates to methods of fabricating semiconductor devices, by which a polymer layer may be formed on a photoresist pattern so that critical dimensions (CDs) may be uniform regardless of the position of the semiconductor device, that is, regardless of whether the semiconductor device is fabricated at the center or the edge of a semiconductor substrate.

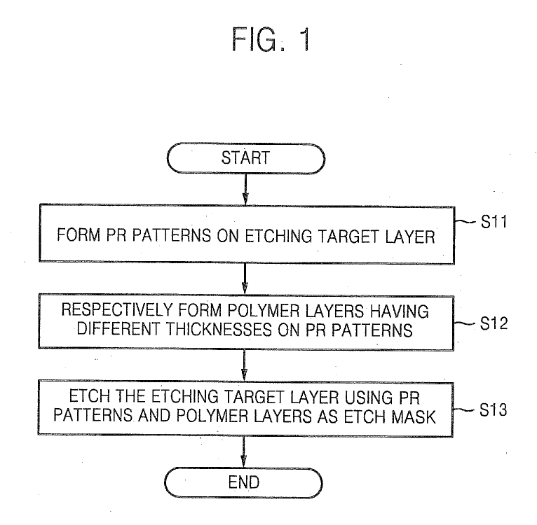

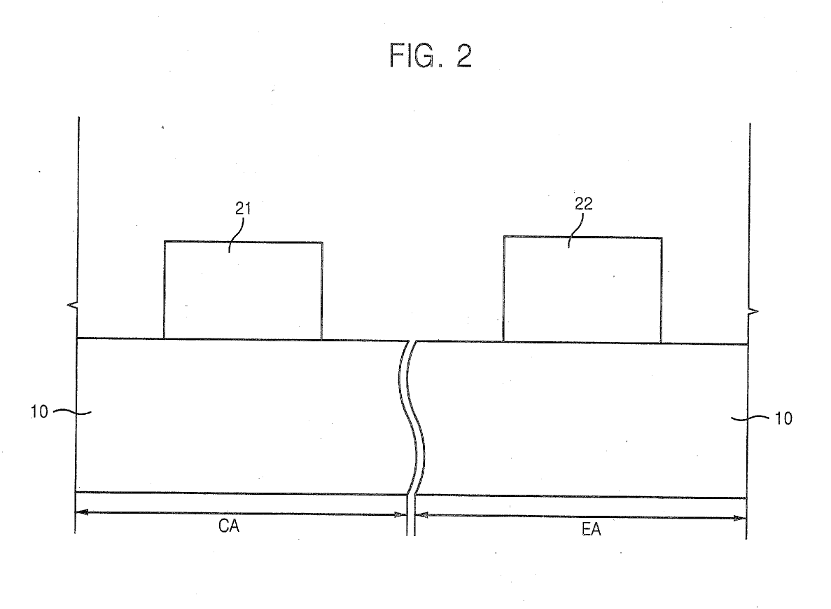

Hereinafter, a method of fabricating semiconductor devices according to some embodiments of the present invention will be described with reference to FIGS. 1 through 4. FIG. 1 presents a flowchart of a method of fabricating semiconductor devices according to some embodiments of the present invention and FIGS. 2 through 4 present cross-sectional views of stages in the method of fabricating semiconductor devices according to some embodiments of the present invention.

Referring to FIG. 1, photoresist (PR) patterns may be formed on an etching target layer in procedure S11. Referring to FIG. 2, a PR layer (not shown) having a predetermined thickness may be formed on a central area (CA) and an edge area (EA) of the etching target layer and then desired PR patterns 21 and 22 may be formed using photolithography. The etching target layer 10 may be a semiconductor layer, an interlayer insulating layer, or a conductive layer.

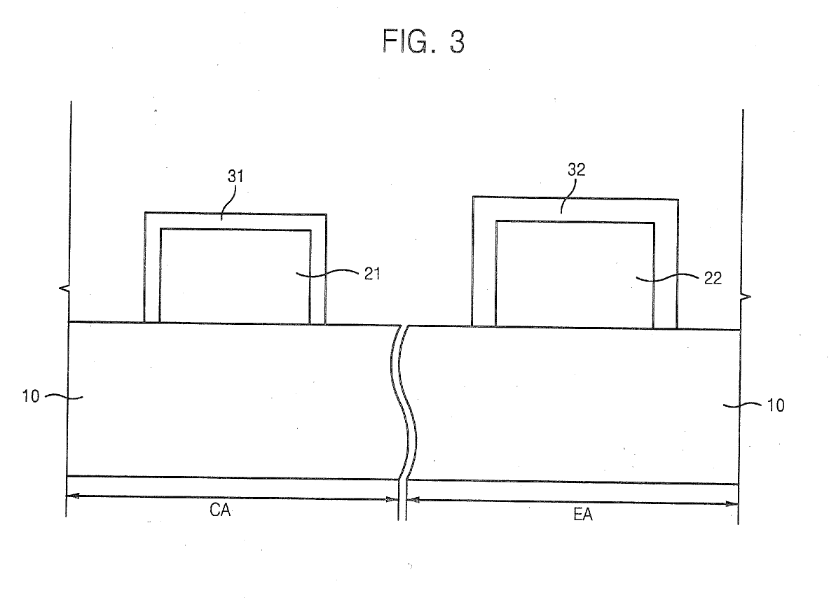

Referring again to FIG. 1, polymer layers may be respectively formed on the PR patterns to different levels of thickness in procedure S12. Referring to FIG. 3, polymer layers 31 and 32 having different thicknesses may be formed by flowing reactant gas onto the PR patterns 21 and 22 and selectively reacting the reactant gas to the PR patterns 21 and 22. Selective reaction between the reactant gas and the PR patterns 21 and 22 may be controlled by the type of reactant gas, the pressure of the reactant gas, reaction temperature, power used for the reaction, etc. Accordingly, when these factors are controlled, the polymer layers 31 and 32 may be formed to different thicknesses according to the positions of the PR patterns 21 and 22.

As illustrated in FIG. 3, when more CD loss occurs in the PR pattern 22 positioned at the edge area EA of the etching target layer 10 than in the PR pattern 21 at the central area CA of the etching target layer 10, the polymer layer 32 on the PR pattern 22 positioned at the edge area EA of the etching target layer 10 may be formed to a greater thickness than the polymer layer 31 on the PR pattern 21 positioned at the central area CA of the etching target layer 10. Although not shown, if more CD loss occurs at the central area CA of the etching target layer 10 than at the edge area EA of the etching target layer 10, a polymer layer on the PR pattern 21 positioned at the central area CA may be formed to a greater thickness than that on the PR pattern 22 positioned at the edge area EA.

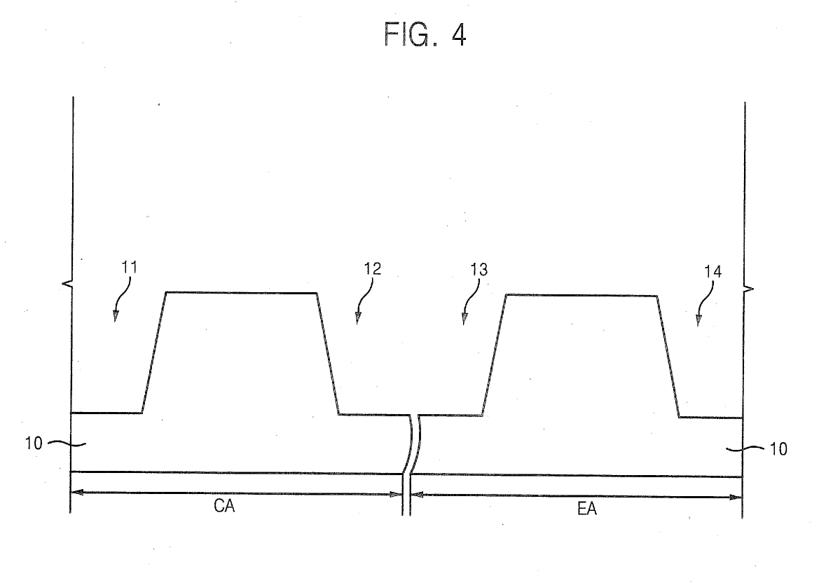

Referring again to FIG. 1, the etching target layer may be etched using the PR patterns and the polymer layers as an etch mask in procedure S13. Referring to FIG. 4, the etching target layer 10 may be etched using the PR patterns 21 and 22 (FIG. 3) and the polymer layers 31 and 32 (FIG. 3) on the PR patterns 21 and 22 as an etch mask. The edge area EA of the etching target layer 10 may be etched using an etch mask including the PR pattern 22 and the thicker polymer layer 32. Accordingly, even when the PR pattern 22 positioned at the edge area EA of the etching target layer 10 is subjected to more CD loss than the PR pattern 21 positioned at the central area CA of the etching target layer 10, the PR pattern 22 can be complemented by the thicker polymer layer 32. More specifically, while the etching target layer 10 is being etched, the PR patterns 21 and 22 and the polymer layers 31 and 32 having different thicknesses can effectively function as an etch mask so that CDs of various semiconductor devices can be controlled to be at least uniform after the etching process of the etching target layer 10.

When the etching target layer 10 is a semiconductor layer, trenches 11, 12, 13, and 14 shallow trench isolation (STI) regions may be formed by an etching process. Alternatively, although not shown, when the etching target layer 10 is an interlayer insulating layer, contact holes or via holes may be formed by etching. When the etching target layer 10 is a conductive layer, a wiring pattern may be formed by an etching process.

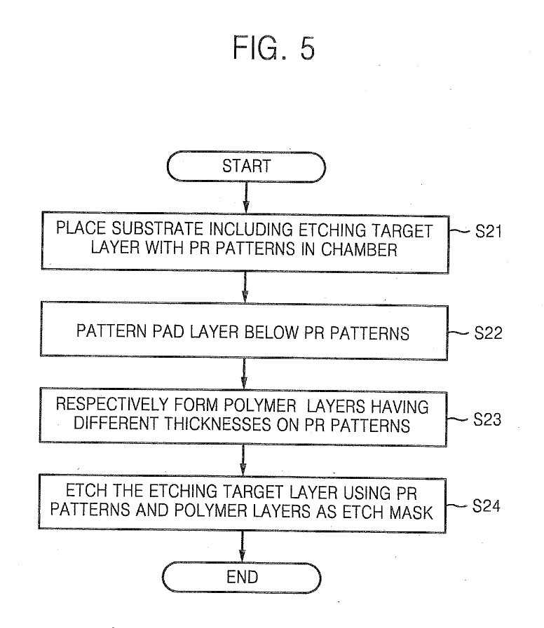

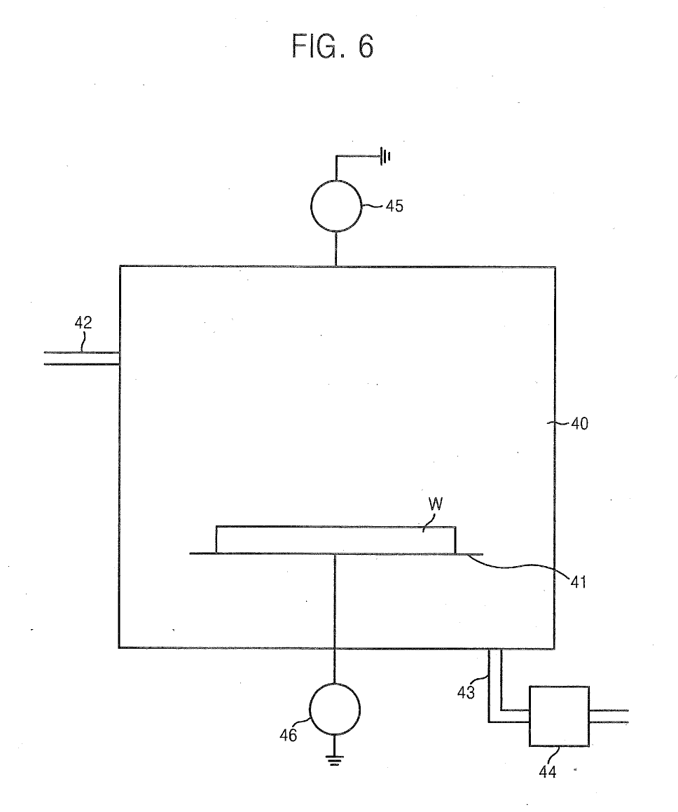

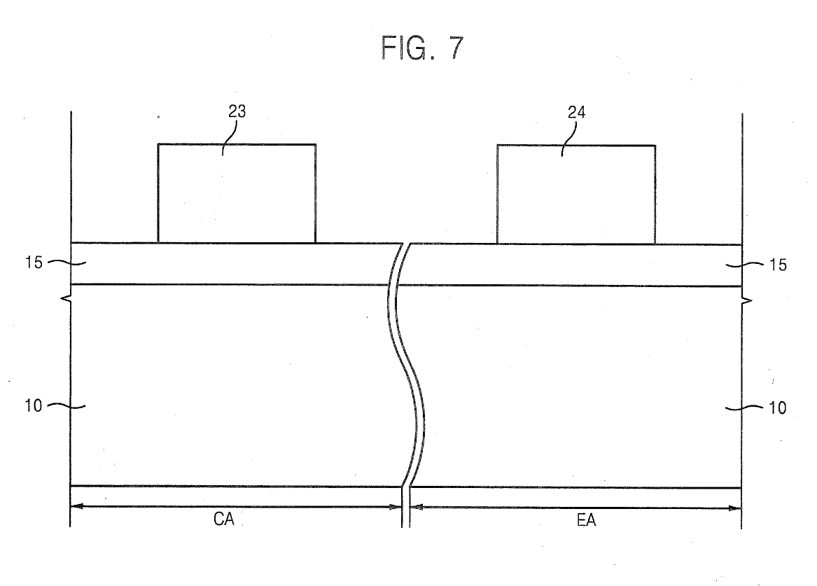

A method of fabricating semiconductor devices according to other embodiments of the present invention will be described below with reference to FIGS. 5 through 10. FIG. 5 presents a flowchart of a method of fabricating semiconductor devices according to embodiments of the present invention. FIG. 6 illustrates a dry etching system used in methods according to the present invention. FIGS. 7 through 10 present cross-sectional views of stages in methods according to some embodiments of the present invention. In particular embodiments of the present invention, an etching target layer is a semiconductor layer. However, according to other embodiments of the present invention, the methods described herein can also be used when the etching target layer is an interlayer insulating layer or a conductive layer.

Referring to FIG. 5, a substrate including an etching target layer on which PR patterns are formed may be placed within a chamber in procedure S21.

Referring to FIG. 6, a substrate W including an etching target layer may be placed within a chamber 40 of the dry etching system. The chamber 40 may be equipped with a mount 41 on which the substrate W including the etching target layer to be etched may be placed. The mount 41 includes a heater or a cooler (not shown) for controlling the temperature of the substrate W. Also, the chamber 40 includes a gas inlet 42 through which plasma gas, reactant gas, or etch gas is supplied, a gas outlet 43 through which gas is discharged and internal pressure is controlled, and a pump 44. A source power supply 45 which supplies power for generating plasma is connected to the top of the chamber 40. A bias power supply 46 which supplies power to the substrate W is connected to the mount 41. The source power supply 45 supplies power converting gas into plasma and the bias power supply 46 supplies power forming a potential difference which may cause the plasma to collide with the substrate W.

Referring to FIG. 7, the substrate W, e.g., a silicon semiconductor wafer, placed within the chamber 40 of the dry etching system includes predetermined PR patterns 23 and 24 on the central area CA and the edge area EA, respectively, of the etching target layer 10. A pad layer 15 may be formed between the PR patterns 23 and 24 and the etching target layer 10. Although not shown, the pad layer 15 may have a stack structure of, for example, a pad oxide layer and a pad nitride layer. In addition, although not shown, a bottom anti-reflective coating (BARC) layer may be further formed between the pad layer 15 and the PR patterns 23 and 24.

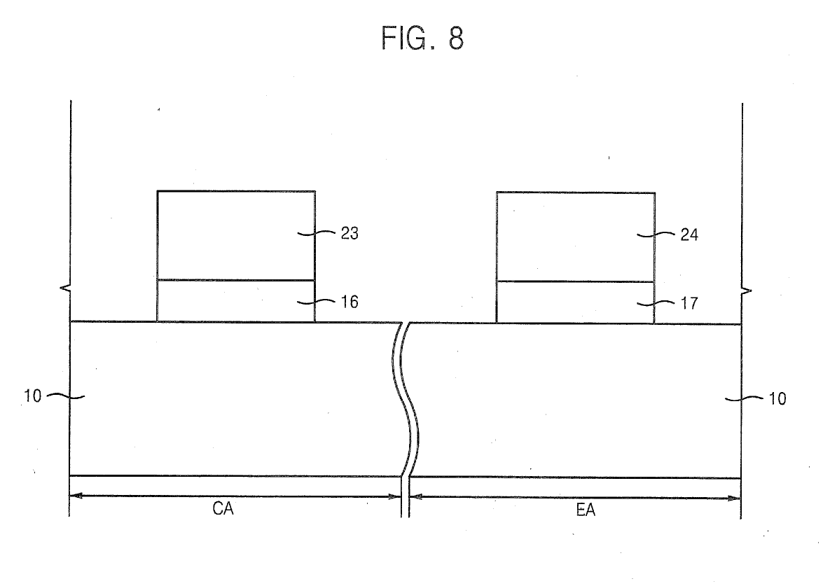

Referring to FIG. 8, the pad layer 15 (FIG. 7) may be etched using the PR patterns 23 and 24 as an etch mask and patterned into pad patterns 16 and 17 in procedure S22 (FIG. 5). This procedure may be performed using a typical dry etch process using plasma.

Referring again to FIG. 5, in process S23, polymer layers having different thicknesses may be formed on the PR patterns, respectively, by controlling the pressure, source power, bias power, and the flow rate of reactant gas in the chamber. These polymer layers are formed in-situ. Here, when more CD loss occurs in the PR pattern positioned at the edge area of the etching target layer than in the PR pattern positioned at the central area of the etching target layer, the polymer layer on the edge area of the etching target layer may be formed thicker than the polymer layer on the central area of the etching target layer. However, such aspects of the present invention are not restricted to the above-described embodiments.

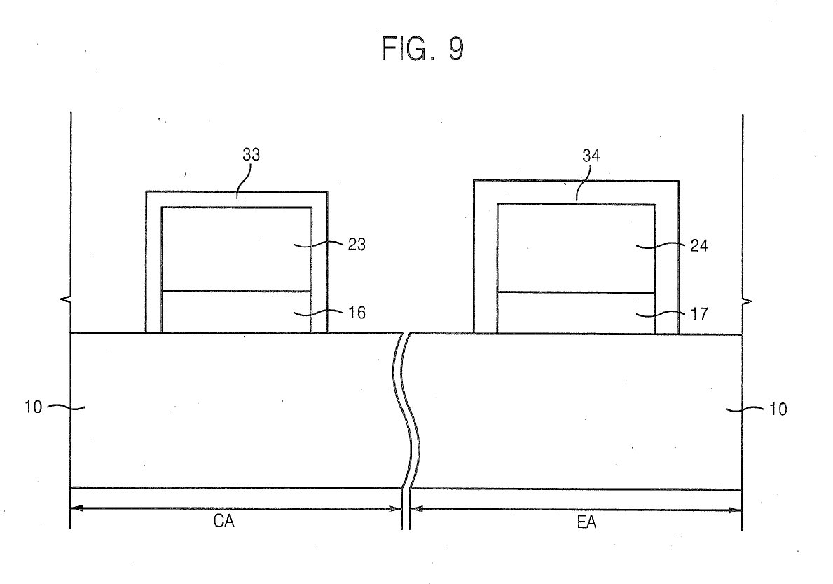

Referring to FIGS. 6 and 9, reactant gas may be supplied into the chamber 40 through the gas inlet 42. The reactant gas may be CₓF_{y} gas or CₐH_{b}F_{c} gas, including, but not limited to, CF₄, CHF₃, C₂F₆, C₄F₈, CH₂F₂, CH₃F, CH₄, C₂H₂, or C₄F₆ gas. During this time, the flow rate of the reactant gas may be about 50 through 250 sccm. In addition, inert gas such as He, Ar, Xe, or I may also be supplied into the chamber 40 at least in part to stably generate plasma. The flow rate of the inert gas may be about 500 sccm or less. The internal pressure of the chamber 40 may be about 20 through 300 mT. The power of the source power supply 45, i.e., source power, may be about 100 through 400 W. The power of the bias power supply 46, i.e., bias power may be about 0 through 150 W and, in some embodiments, about 0 through 30 W.

Under the conditions of the above-described pressure, source power, bias power, and flow rate of the reactant gas, the reactant gas may selectively react to the PR patterns 23 and 24 and form polymer layers 33 and 34. As illustrated in FIG. 9 and as will be illustrated in exemplary experiments, the polymer layer 34 formed on the PR pattern 24 positioned at the edge area EA of the etching target layer 10 may be thicker than the polymer layer 33 formed on the PR pattern 23 positioned at the central area CA of the etching target layer 10. Meanwhile, the reactant gas limitedly reacts to the exposed portion of the etching target layer 10 under the above-described conditions, and thus, rarely forms a polymer layer on the exposed portion of the etching target layer 10. Accordingly, the exposed top of the etching target layer 10 shows little change, and therefore, the polymer layer that may be formed on the exposed portion of the etching target layer 10 is not separately illustrated in the drawings.

Referring again to FIG. 5, the etching target layer is etched using the PR patterns and the polymer layers as an etch mask in procedure S24.

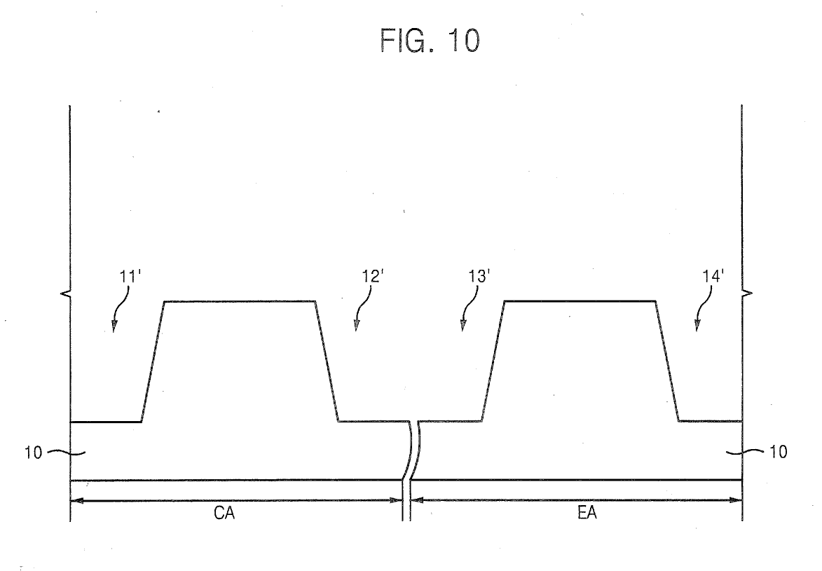

Referring to FIG. 10, the etching target layer 10 may be etched using the pad patterns 16 and 17 (FIG. 9), the PR patterns 23 and 24 (FIG. 9), and the polymer layers 33 and 34 (FIG. 9), which are sequentially formed on the etching target layer 10, as an etch mask. The edge area EA of the etching target layer 10 is etched using an etch mask including the PR pattern 24 and the thicker polymer layer 34. Accordingly, even when the PR pattern 24 positioned at the edge area EA of the etching target layer 10 is subjected to more CD loss than the PR pattern 23 positioned at the central area CA of the etching target layer 10, the PR pattern 24 can be complemented by the thicker polymer layer 34. More specifically, while the etching target layer 10 is being etched, the PR patterns 23 and 24 and the polymer layers 33 and 34 having different thicknesses can effectively function as an etch mask so that CDs of various semiconductor devices can be controlled to be uniform after etching the etching target layer 10.

When the etching target layer 10 is a semiconductor layer, trenches 11′, 12′, 13′, and 14′ for STI regions may be formed by etching. Alternatively, although not shown, when the etching target layer 10 is an interlayer insulating layer, contact holes or via holes may be formed by etching. When the etching target layer 10 is a conductive layer, a wiring pattern may be formed by etching.

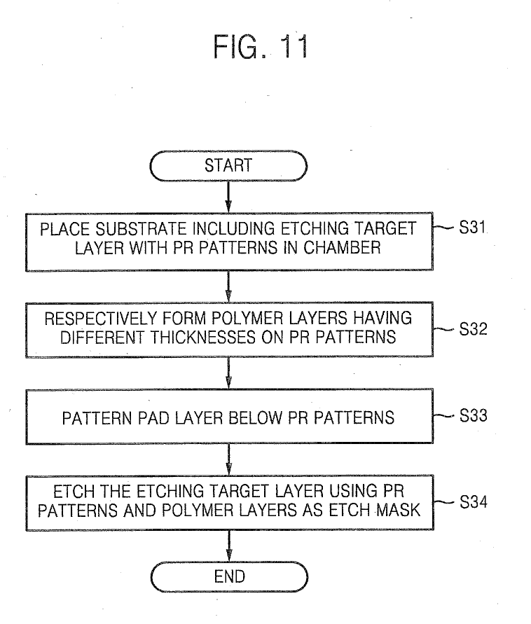

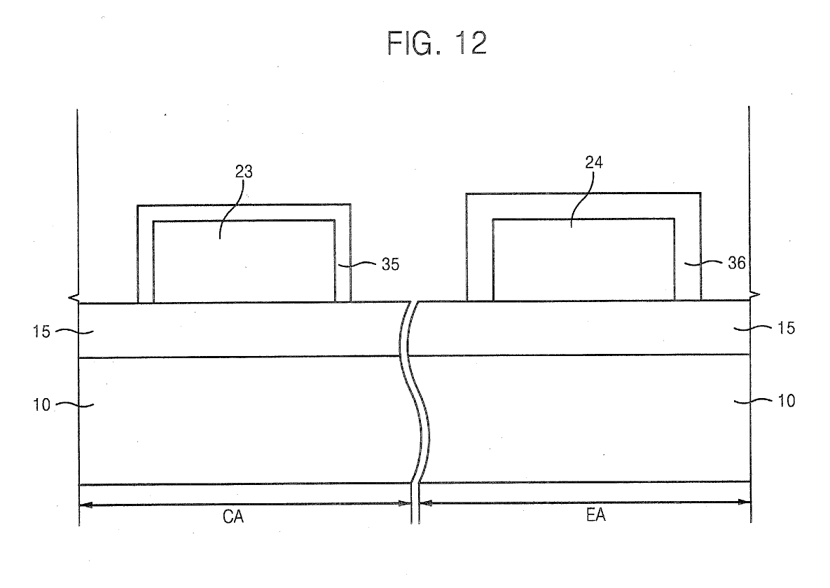

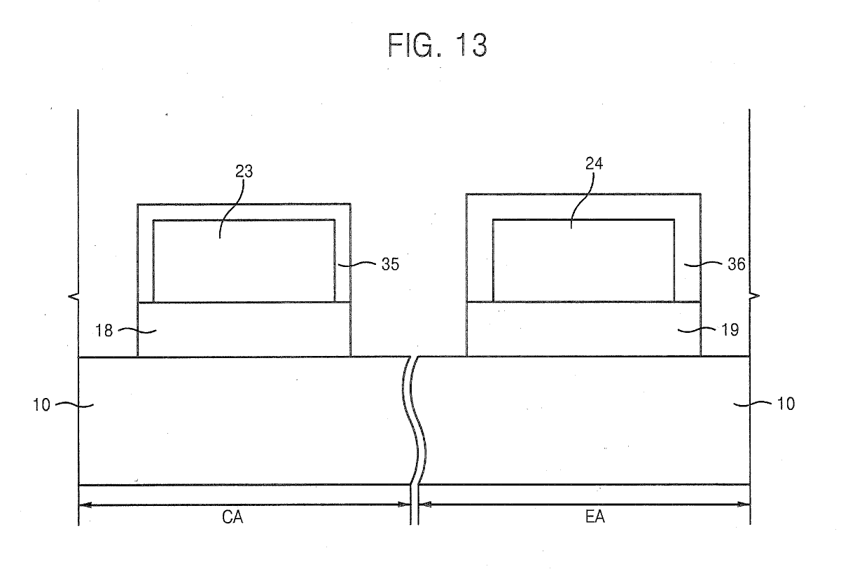

A method of fabricating semiconductor devices according to further embodiments of the present invention will be described below with reference to FIG. 7 and FIGS. 10 through 13. FIG. 11 presents a flowchart of a method of fabricating semiconductor devices according to further embodiments of the present invention. FIGS. 12 and 13 present cross-sectional views of stages in the method.

The method according to the present embodiment is at least substantially similar to the method described with reference to FIGS. 5 through 10, with the exception that polymer layers are respectively formed on PR patterns before a pad layer is patterned into pad patterns. Significant differences between the methods will be generally described. In this instance, it is assumed that an etching target layer is a semiconductor layer, however, some embodiments of the present invention can also be used when the etching target layer is an interlayer insulating layer or a conductive layer.

Referring to FIG. 11, a substrate including an etching target layer on which PR patterns are formed may be placed within a chamber in procedure S31. As illustrated in FIG. 7, the substrate W, in which the pad layer 15 and the PR patterns 23 and 24 are formed on the etching target layer 10, may be placed in the chamber 40 of the dry etching system (FIG. 6) in procedure S31. The dry etching system has been described with reference to FIG. 6, and thus, further description thereof is omitted here.

Referring again to FIG. 11, in procedure S32, polymer layers having different thicknesses may be formed on the PR patterns, respectively, by controlling the pressure, source power, bias power, and the flow rate of reactant gas in the chamber. As illustrated in FIG. 12, it is believed that more CD loss occurs in the PR pattern 24 positioned at the edge area EA of the etching target layer 10 than in the PR pattern 23 positioned at the central area CA of the etching target layer 10 and the polymer layer 24 on the edge area EA is formed to an extent that is thicker than the polymer layer 23 on the central area CA. The polymer layers 35 and 36 are formed by allowing reactant gas to selectively react to the PR patterns 23 and 24. The reactant gas may be C_{c}F_{y} gas or CₐH_{b}F_{c} gas, and non-limiting examples include CF₄, CHF₃, C₂F₆, C₄F₈, CH₂F₂, CH₃F, CH₄, C₂H₂, or C₄F₆ gas. The reactant gas is supplied into the chamber 40 (FIG. 6) at a flow rate of, for example, about 50 through 250 standard cubic centimeters per minute (sccm). In addition to the reactant gas, inert gas such as He, Ar, Xe, or I may also be supplied into the chamber 40 at a flow rate of, for example, about 500 sccm or less in order to stably generate plasma. The internal pressure of the chamber 40 may be about 20 through 300 mT. The source power may be about 100 through 400 W. The bias power may be about 0 through 150 W, and in some embodiments, about 0 through 30 W.

Under the conditions of the above-described pressure, source power, bias power, and flow rate of the reactant gas, as illustrated in FIG. 12, the polymer layer 36 formed on the PR pattern 24 positioned at the edge area EA of the etching target layer 10 may be thicker than the polymer layer 35 formed on the PR pattern 23 positioned at the central area CA of the etching target layer 10.

Referring to FIG. 13, the pad layer 15 (FIG. 12) may be etched using the PR patterns 23 and 24 and the polymer layers 35 and 36 as an etch mask and patterned into pad patterns 18 and 19 in procedure S33 (FIG. 11). This procedure may be performed in-situ using typical dry etch using plasma.

Referring again to FIG. 11, the etching target layer may be etched using the PR patterns and the polymer layers as an etch mask in procedure S34.

Referring to FIG. 10, the etching target layer 10 may be etched using the pad patterns 18 and 19 (FIG. 13), the PR patterns 23 and 24 (FIG. 13), and the polymer layers 35 and 36 (FIG. 13), which are sequentially formed on the etching target layer 10, as an etch mask. The edge area EA of the etching target layer 10 may be etched using an etch mask including the PR pattern 24 (FIG. 13) and the thicker polymer layer 36 (FIG. 13). Accordingly, even when the PR pattern 24 positioned at the edge area EA of the etching target layer 10 is subjected to more CD loss than the PR pattern 23 positioned at the central area CA of the etching target layer 10, the PR pattern 24 can be complemented by the thicker polymer layer 36. More specifically, while the etching target layer 10 is being etched, the PR patterns 23 and 24 and the polymer layers 35 and 36 having different thicknesses can effectively function as an etch mask so that CDs of various semiconductor devices can be controlled to be uniform after etching the etching target layer 10.

Hereinafter, the present invention will be described in more detail by reference to exemplary experiments. However, it will be understood that the exemplary experiments do not restrict the present invention to the embodiments described therein.

### EXAMPLES

### Example 1

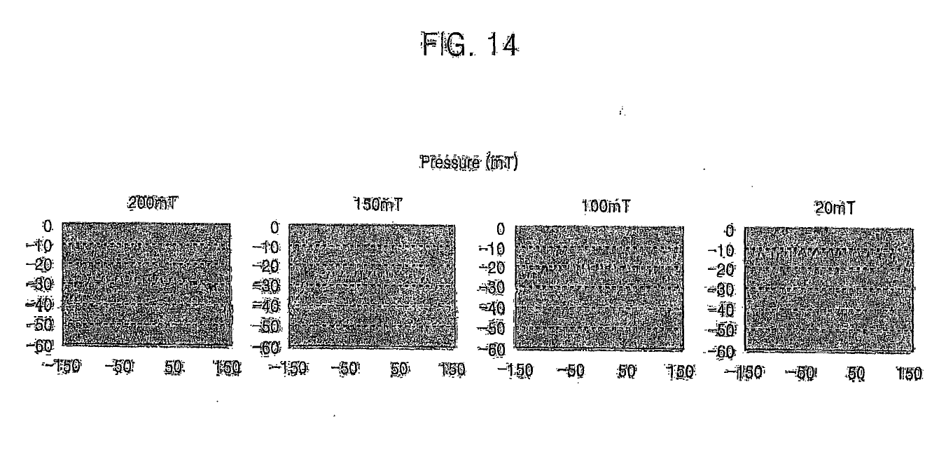

A pad oxide layer, a pad nitride layer, and an anti-reflective layer were sequentially formed on a 12-inch semiconductor wafer. Thereafter, a PR layer was formed on the semiconductor wafer and then patterned using photolithography to form PR patterns. Next, the pad oxide layer, the pad nitride layer, and the anti-reflective layer were etched using the PR patterns as an etch mask and patterned into pad oxide patterns, pad nitride patterns, and anti-reflective patterns. Subsequently, the semiconductor wafer having the PR patterns was placed on a mount within a chamber of a TEL SCCM poly etcher. CHF₃ was supplied into the chamber at a flow rate of 200 sccm. Under the conditions of a source power of 200 W and a bias power of 50 W, the thicknesses of polymer layers formed on the PR patterns were observed while the internal pressure of the chamber was changed from 20 mT to 200 mT. The results of the observation are illustrated in FIG. 14.

In the graphs illustrated in FIG. 14, the X-axis indicates a position on the semiconductor wafer in mm units and the Y-axis indicates a value, which is obtained by subtracting the thickness of a structure in which a polymer layer is formed on a PR pattern from the thickness of the original PR pattern, in nm units. As illustrated in FIG. 14, a polymer layer formed on a PR pattern at the edge area of the semiconductor wafer is thicker than the polymer layer at the center area thereof.

### Example 2

The second exemplary experiment was performed under the same conditions as the first exemplary experiment described above with the exception that the flow rate of CHF₃ was changed from 100 to 200 sccm and the flow rate of He was changed from 0 to 400 sccm at an internal pressure of 200 mT, at a source power of 200 W, and at a bias power of 50 W. The results of observing the thickness of a polymer formed on a PR pattern are illustrated in FIG. 15. As illustrated in FIG. 15, a polymer layer formed on a PR pattern at the edge-area of the semiconductor wafer is thicker than the polymer layer at the center area thereof.

### Example 3

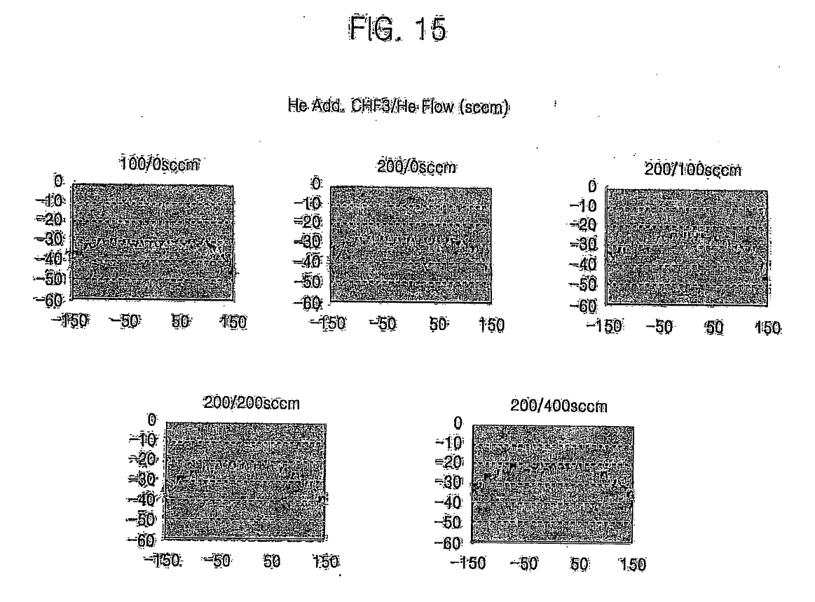

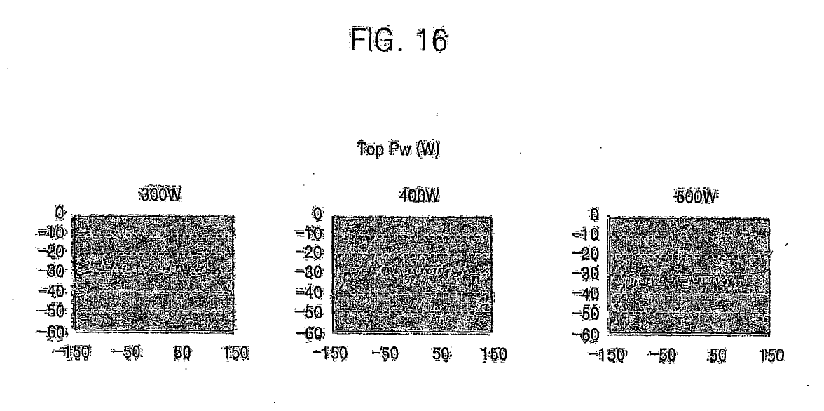

The third exemplary experiment was performed under the same conditions as the first exemplary experiment described above with the exception that the source power was changed from 300 to 500 W at an internal pressure of 200 mT, at a bias power of 50 W, and a CHF₃ flow rate of 200 sccm. The results from observing the thickness of a polymer formed on a PR pattern are illustrated in FIG. 16. As illustrated in FIG. 16, a polymer layer formed on a PR pattern at the edge area of the semiconductor wafer is thicker than the polymer layer at the center area thereof.

### Example 4

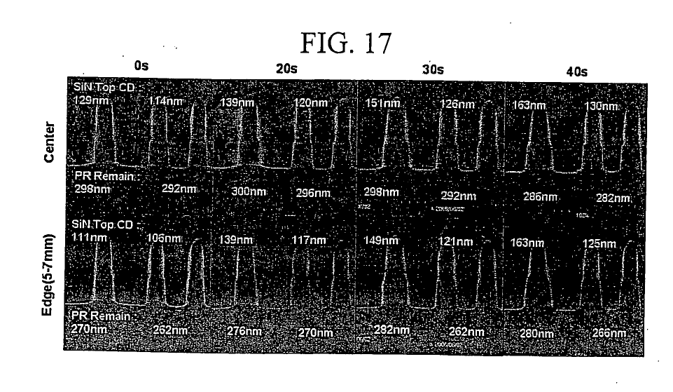

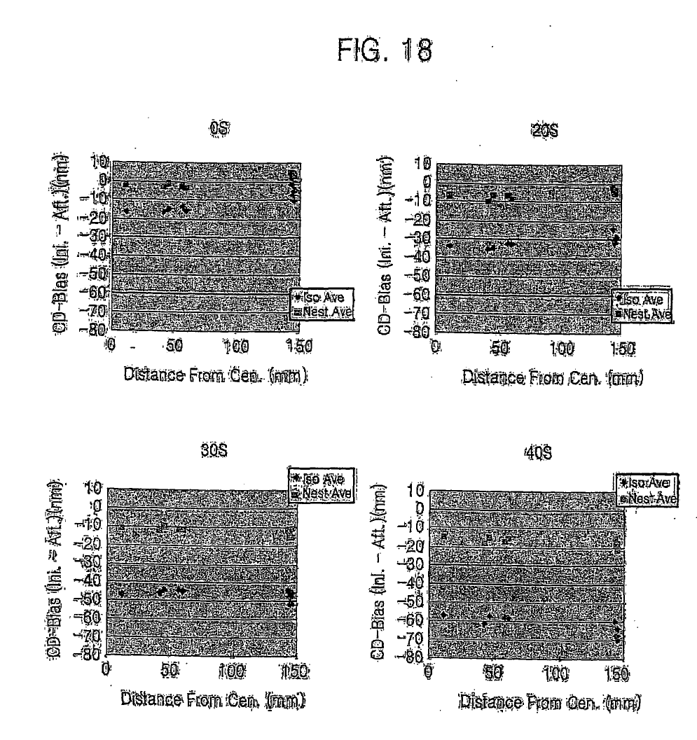

The fourth exemplary experiment was performed under the same conditions as the first exemplary experiment described above with the exception that the polymer deposition time was changed from 0 to 40 seconds at an internal pressure of 200 mT, at a source power of 400 W, at a bias power of 50 W, and at a CHF₃ flow rate of 200 sccm. The results from observing the thickness of a polymer formed on a PR pattern are illustrated in FIGS. 17 and 18. As illustrated in FIGS. 17 and 18, at a point of 0 s when polymer deposition has not been started, CDs of PR patterns are not uniform between the central area of the semiconductor wafer and the edge area of the semiconductor wafer. However, when time lapses, the CDs of PR patterns gradually become uniform and at a point of 30 s when polymer deposition has been performed for 30 seconds, PR patterns at the central area of the semiconductor wafer have almost the same CDs as PR patterns at the edge area of the semiconductor wafer.

### Example 5

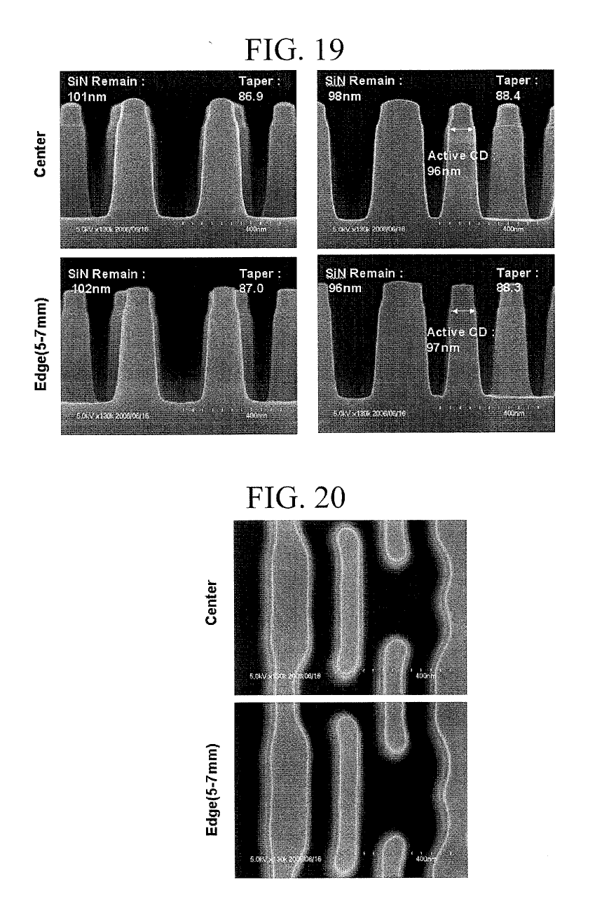

A pad oxide layer, a pad nitride layer, and an anti-reflective layer were sequentially formed on a 12-inch semiconductor wafer. Thereafter, a PR layer was formed on the semiconductor wafer and then patterned using photolithography to form PR patterns. Next, the pad oxide layer, the pad nitride layer, and the anti-reflective layer were etched using the PR patterns as an etch mask and patterned into pad oxide patterns, pad nitride patterns, and anti-reflective patterns. Subsequently, the semiconductor wafer having the PR patterns was placed on a mount within a chamber of a TEL SCCM poly etcher. Polymer deposition was performed for 30 seconds at an internal pressure of 200 mT, at a source power of 400 W, at a bias power of 50 W, and at a CHF₃ flow rate of 200 sccm. Thereafter, the semiconductor wafer was etched using the PR patterns, upon which a polymer layer had been formed, as an etch mask, thereby forming trenches for STI. Next, the PR patterns were removed. Resultant structures are illustrated in FIGS. 19 and 20.

As illustrated in FIGS. 19 and 20, silicon nitrides have almost the same CDs between the central area and the edge area of the semiconductor wafer. Also, the internal slopes of the trenches are similar between the central and edge areas of the semiconductor wafer.

As described above, embodiments of the present invention allow a polymer layer formed on a PR pattern to have a different thickness according to the position of the PR pattern on an etching target layer so that a polymer layer on a PR pattern, which may have more CD loss at its position, is formed thicker than polymer layers in other areas. As a result, the thicker polymer layer can complement the PR pattern that has more CD loss, and therefore, the CD uniformity of semiconductor devices can be improved.

While the present invention has been shown and described with reference to exemplary embodiments thereof, it will be understood by those of ordinary skill in the art that various changes in form and detail may be made herein without departing from the spirit and scope of the present invention, as defined by the following claims.

What is claimed is:

1. A method of fabricating semiconductor devices, comprising:
forming a polymer layer on a photoresist pattern on an etching target layer by selectively reacting a reactant gas with the photoresist pattern to provide different thicknesses of the polymer layer according to the position of the photoresist pattern; and
etching the etching target layer using the photoresist pattern and the polymer layer as an etch mask.

2. The method of claim 1, wherein the polymer layer formed on a photoresist pattern at an edge area of the etching target layer is thicker than a polymer layer formed on a photoresist pattern at a central area of the etching target layer.

3. The method of claim 1, wherein the etching target layer is a layer selected from the group consisting of a semiconductor layer, an interlayer insulating layer, and a conductive layer.

4. The method of claim 3, wherein etching the etching target layer comprises etching the semiconductor layer to form trenches for shallow trench isolation (STI) regions on the semiconductor layer.

5. The method of claim 3, wherein etching the etching target layer comprises etching the interlayer insulating layer to form contact holes or via holes.

6. The method of claim 3, wherein etching the etching target layer comprises etching the conductive layer to form a wiring pattern.

7. A method of fabricating semiconductor devices, comprising:
forming a polymer layer on a photoresist pattern, wherein the polymer layer has a different thicknesses according to positions of the photoresist pattern by controlling an internal pressure, source power, bias power, and a flow rate of reactant gas during the process in which formation of the polymer layer occurs; and
etching an etching target layer using the photoresist pattern and the polymer layers as an etch mask.

8. The method of claim 7, wherein forming the polymer layer comprises forming the polymer layer at an internal pressure in a range of about 20 to 300 mT, at a source power in a range of about 100 to 400 W, at a bias power in a range of about 0 to 150 W, and having a reactant gas flow rate in a range of about 50 to 250 sccm.

9. The method of claim 8, wherein forming the polymer layer further comprises supplying inert gas at a flow rate of about 500 sccm or less.

10. The method of claim 7, wherein the polymer layer formed on a photoresist pattern at an edge area of the etching target layer is thicker than a polymer layer formed on a photoresist pattern at a central area of the etching target layer.

11. The method of claim 7, further comprising forming a pad layer on the etching target layer before the photoresist pattern is formed on the etching target layer.

12. The method of claim 11, further comprising patterning the pad layer into pad patterns using the photoresist patterns as an etch mask.

13. The method of claim 12, wherein forming the polymer layer is performed before or after patterning the pad layer.

14. The method of claim 7, wherein etching target layer is selected from the group consisting of a semiconductor layer, an interlayer insulating layer, and a conductive layer.

15. The method of claim 14, wherein etching the etching target layer comprises etching the semiconductor layer to form trenches for shallow trench isolation (STI) regions on the semiconductor layer.

16. The method of claim 14, wherein etching the etching target layer comprises etching the interlayer insulating layer to form contact holes or via holes.

17. The method of claim 14, wherein etching the etching target layer comprises etching the conductive layer to form a wiring pattern.

18. The method of claim 7, wherein the photoresist pattern is formed on a substrate comprising an etching target layer.

19. The method of claim 7, wherein the photoresist pattern is formed on a semiconductor wafer.

20. The method of claim 19, wherein a polymer layer formed on a photoresist pattern at an edge area of the semiconductor wafer is thicker than a polymer layer formed on a photoresist pattern at a central area of the semiconductor wafer.
